(19) United States
(12) Patent Application Publication
(10) Pub. No.: US 2011/0217465 A1
(43) Pub. Date: Sep. 8, 2011

(54) SHIELDS FOR SUBSTRATE PROCESSING SYSTEMS

(75) Inventors: Karl Leeser, San Jose, CA (US); Yajie Liu, San Jose, CA (US)

(73) Assignee: Novellus Systems Inc., San Jose, CA (US)

(21) Appl. No.: 13/039,641

(22) Filed: Mar. 3, 2011

Related U.S. Application Data
(60) Provisional application No. 61/311,655, filed on Mar. 8, 2010.

(51) Int. Cl. C23C 16/00

(52) U.S. Cl. 427/248.1; 118/728

(57) ABSTRACT

A shielding system for a physical vapor deposition (PVD) chamber is disclosed. The PVD chamber includes a pedestal supporting a substrate. The shielding system includes a first annular portion and a second annular portion of a pedestal shield. The first annular portion is attached the pedestal at a first location. The first annular portion is located at or below a plane including the substrate. The second annular portion is attached to the pedestal at a second location that is below the first location. The first annular portion is spaced a predetermined distance from the second annular portion and is electrically isolated from the second annular portion.

### CROSS-REFERENCE TO RELATED APPLICATIONS

This application claims the benefit of U.S. Provisional Application No. 61/311,655, filed on Mar. 8, 2010. The disclosure of the above application is incorporated herein by reference in its entirety.

### FIELD

The present disclosure relates to shields for substrate processing systems, and more particularly to shields for physical vapor deposition (PVD) systems.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Physical vapor deposition (PVD) systems are used to deposit metal layers onto substrates such as semiconductor wafers. The metal layers can be used as diffusion barriers, adhesion or seed layers, primary conductors, antireflection coatings, etch stops, etc.

In PVD systems, a plasma feed gas such as Argon is introduced into a processing chamber. Electrons collide with atoms of the plasma feed gas to create ions. In some applications, magnetic fields are used to increase a residence time of the electrons by causing the electrons to spiral through the plasma.

A negative potential applied to a cathode attracts the ions towards a target. The ions collide with the target with high energy. Target atoms are dislodged from the surface of the target by direct momentum transfer. The impact of the ions on the target also releases secondary electrons. The dislodged atoms and ions (electrostatically attracted by the secondary electrons) are then deposited on a substrate such as a semiconductor wafer. While deposition on the substrate is desirable, it is important to limit deposition on other components in the processing chamber. One or more shields may be used in the processing chamber to protect components of the processing chamber from undesired deposition.

Referring now to FIGS. 1 and 2, an example of a pedestal shield typically used in PVD systems is shown. In FIG. 1, a cross-section of a portion of a processing chamber 10 is shown. In the processing chamber 10, a substrate such as a semiconductor wafer (hereinafter wafer) 12 is positioned on a wafer holder or a pedestal 14 as shown. The processing chamber 10 includes a wall shield (or a sidewall shield) 16, which is grounded to the processing chamber 10. Additionally, a pedestal shield 18 is included to protect a chamber wall of the processing chamber 10 and a ring portion 20 of the pedestal 14 from unwanted deposition of metal particles. The ring portion 20 of the pedestal 14 is made of an electrically insulating material such as ceramic. The pedestal shield 18 and the wall shield 16 are typically made of metal and act as a capacitance C1.

During deposition, a radio frequency (RF) bias is applied to the wafer 12 through the pedestal 14, and a target mounted on a top wall of the processing chamber 10 is energized to eject metal particles. Plasma distribution along a surface of the wafer 12 is not uniform because a plasma boundary (a boundary condition) is located at an edge of the wafer 12.

In addition, when the RF bias is applied to the wafer 12 through the pedestal 14, an RF level at the edge of the wafer 12 is affected due to the boundary condition. Specifically, RF loss through the pedestal shield 18 to the wall shield 16 causes a lateral RF effect (an edge effect) at the edge of the wafer 12.

In FIG. 2, an expanded view of a portion of FIG. 1 is shown to illustrate film accumulation on an inner diameter of the ring portion 20. The film accumulation occurs because the ring portion 20 slopes downward towards the wafer 12 at the inner diameter of the ring portion 20.

### SUMMARY

A shielding system for a physical vapor deposition (PVD) chamber is disclosed. The PVD chamber includes a pedestal supporting a substrate. The shielding system includes a first annular portion and a second annular portion of a pedestal shield. The first annular portion is attached the pedestal at a first location. The first annular portion is located at or below a plane including the substrate. The second annular portion is attached to the pedestal at a second location that is below the first location. The first annular portion is spaced a predetermined distance from the second annular portion and is electrically isolated from the second annular portion.

In other features, second annular portion of the pedestal shield includes a straight portion and a curved portion. The straight portion is attached to the second location, is generally perpendicular to the plane including the substrate and extends from the pedestal towards a bottom chamber wall. The curved portion extends from the straight portion towards a side chamber wall.

In other features, the first annular portion of the pedestal shield and the straight portion of the second annular portion of the pedestal shield are adjacent to a ring portion of the pedestal. An upper surface of the ring portion slopes downwardly from a radially inner diameter to a radially outer diameter.

In other features, the shielding system further includes a wall shield. The wall shield extends inwardly from the side chamber wall towards the pedestal. The wall shield overlaps a radially outer portion of the second annular portion of the pedestal shield.

In other features, the curved portion of the second annular portion of the pedestal shield is concave relative to a top chamber wall, and the wall shield is concave relative to the top chamber wall.

In other features, the first annular portion includes a first portion and a second portion. The first portion is attached to the pedestal and is parallel to the plane including the substrate. The second portion extends in a perpendicular direction from the first portion.

In other features, the second annular portion includes a third portion and a first curved portion. The third portion is attached to the pedestal at the second location and is parallel to the plane including the substrate. The first curved portion extends from the third portion towards a side chamber wall.

In other features, the first curved portion is concave relative to a top chamber wall.

In other features, the first, second, and third portions surround a ring portion of the pedestal. An upper surface of the ring portion slopes downwardly from a radially inner diameter of the ring portion to a radially outer diameter of the ring portion.

In other features, the shielding system further includes a wall shield. The wall shield includes a fourth portion and a second curved portion. The fourth portion is attached to the side chamber wall. The second curved portion extends from the first portion and that is concave relative to a bottom chamber wall.

In other features, a first end of the first curved portion is located inside the second curved portion. A second end of the second curved portion is located inside the first curved portion.

In still other features, a method for shielding in a physical vapor deposition (PVD) chamber. The PVD chamber includes a pedestal supporting a substrate. The method includes attaching a first annular portion of a pedestal shield to the pedestal at a first location at or below a plane including the substrate. The method further includes attaching a second annular portion of the pedestal shield to the pedestal at a second location that is below the first location. The method further includes spacing the first annular portion a predetermined distance from the second annular portion. The method further includes electrically isolating the first annular portion from the second annular portion.

In other features, the method further includes attaching a straight portion of the second annular portion of the pedestal shield to the second location, where the straight portion is generally perpendicular to the plane including the substrate. The method further includes extending the straight portion from the pedestal towards a bottom chamber wall. The method further includes extending a curved portion of the second annular portion of the pedestal shield from the straight portion towards a side chamber wall.

In other features, the method further includes disposing the first annular portion of the pedestal shield and the straight portion of the second annular portion of the pedestal shield adjacent to a ring portion of the pedestal. The method further includes inclining an upper surface of the ring portion to slope downwardly from a radially inner diameter to a radially outer diameter.

In other features, the method further includes extending a wall shield inwardly from the side chamber wall towards the pedestal to overlap a radially outer portion of the second annular portion of the pedestal shield.

In other features, the curved portion of the second annular portion of the pedestal shield is concave relative to a top chamber wall. The wall shield is concave relative to the top chamber wall.

In other features, the method further includes attaching a first portion of the first annular portion to the pedestal, disposing the first portion parallel to the plane including the substrate, and extending a second portion of the first annular portion in a perpendicular direction from the first portion.

In other features, the method further includes attaching a third portion of the second annular portion to the pedestal at the second location, disposing the third portion parallel to the plane including the substrate, and extending a first curved portion of the second annular portion from the third portion towards a side chamber wall.

In another feature, the first curved portion is concave relative to a top chamber wall.

In other features, the method further includes disposing the first, second, and third portions to surround a ring portion of the pedestal. The method further includes inclining an upper surface of the ring portion to slope downwardly from a radially inner diameter of the ring portion to a radially outer diameter of the ring portion.

In other features, the method further includes attaching a fourth portion of a wall shield to the side chamber wall, and extending a second curved portion of the wall shield from the fourth portion, where the second curved portion is concave relative to a bottom chamber wall.

In other features, the method further includes disposing a first end of the first curved portion inside the second curved portion, and disposing a second end of the second curved portion inside the first curved portion.

In still other features, a physical vapor deposition (PVD) chamber includes a pedestal supporting a substrate, where the pedestal includes a ring portion, and where an upper surface of the ring portion slopes downwardly from a radially inner diameter of the ring portion to a radially outer diameter of the ring portion. The PVD chamber further includes a first annular portion of a pedestal shield and a second annular portion of the pedestal shield. The first annular portion is attached to the pedestal and is located at or below a plane including the substrate. The second annular portion includes a straight portion and a first curved portion. The straight portion is generally perpendicular to the plane including the substrate and extends from the first annular portion towards a bottom chamber wall. The first curved portion extends from the straight portion towards a side chamber wall. The first annular portion and the straight portion are adjacent to the ring portion of the pedestal.

In other features, the PVD chamber further includes a wall shield. The wall shield includes a first portion that is attached to the side chamber wall and a second curved portion that extends towards the pedestal.

In another feature, the first curved portion of the pedestal shield overlaps the second curved portion of the wall shield.

In other features, the first curved portion of the pedestal shield is concave relative to a top chamber wall, and the second curved portion of the wall shield is concave relative to the top chamber wall.

In still other features, a method for shielding in a physical vapor deposition (PVD) chamber includes arranging a pedestal configured to support a substrate in the PVD chamber. The method further includes configuring an upper surface of a ring portion of the pedestal to slope downwardly from a radially inner diameter of the ring portion to a radially outer diameter of the ring portion. The method further includes attaching a pedestal shield including a first annular portion and a second annular portion to the pedestal, where the second annular portion includes a straight portion and a first curved portion. The method further includes arranging the first annular portion of the pedestal shield at or below a plane including the substrate. The method further includes arranging the straight portion generally perpendicular to the plane including the substrate, where the straight portion extends from the first annular portion towards a bottom chamber wall. The method further includes arranging the first curved portion to extend from the straight portion towards a side chamber wall. The first annular portion and the straight portion are adjacent to a ring portion of the pedestal.

In another feature, the method further includes attaching a wall shield to the side chamber wall, where the wall shield includes a first portion that is attached to the side chamber wall and a second curved portion that extends towards the pedestal.

In another feature, the method further includes overlapping the first curved portion of the pedestal shield with respect to the second curved portion of the wall shield.

In other features, the first curved portion of the pedestal shield is concave relative to a top chamber wall, and the second curved portion of the wall shield is concave relative to the top chamber wall.

Further areas of applicability of the present disclosure will become apparent from the detailed description provided hereinafter. It should be understood that the detailed description and specific examples are intended for purposes of illustration only and are not intended to limit the scope of the disclosure.

### BRIEF DESCRIPTION OF DRAWINGS

The present disclosure will become more fully understood from the detailed description and the accompanying drawings, wherein:

FIG. 1 illustrates a pedestal shield according to the prior art;

FIG. 2 illustrates film accumulation on an inner diameter of a ring portion of a pedestal;

FIG. 3 illustrates a split pedestal shield according to the present disclosure;

FIG. 4 illustrates another pedestal shield according to the present disclosure; and

FIG. 5 illustrates another implementation of a split pedestal shield according to the present disclosure.

### DETAILED DESCRIPTION

The following description is merely exemplary in nature and is in no way intended to limit the disclosure, its application, or uses. For purposes of clarity, the same reference numbers will be used in the drawings to identify similar elements. As used herein, the phrase at least one of A, B, and C should be construed to mean a logical (A or B or C), using a non-exclusive logical OR. It should be understood that steps within a method may be executed in different order without altering the principles of the present disclosure.

The present disclosure relates to reducing the lateral RF effect at the edge of the wafer and improving plasma uniformity across the wafer. The lateral RF effect at the edge of the wafer can be reduced, and the plasma uniformity can be improved across the wafer in different ways disclosed herein.

For example, the pedestal shield can be split into two shield portions. The geometry and arrangement of the two shield portions relative to other components of the processing chamber can be selected to reduce the lateral RF effect at the edge of the wafer and to improve plasma uniformity across the wafer. Alternatively or additionally, the pedestal shield can be lowered and arranged approximately at or below a level of the wafer to improve plasma uniformity across the wafer.

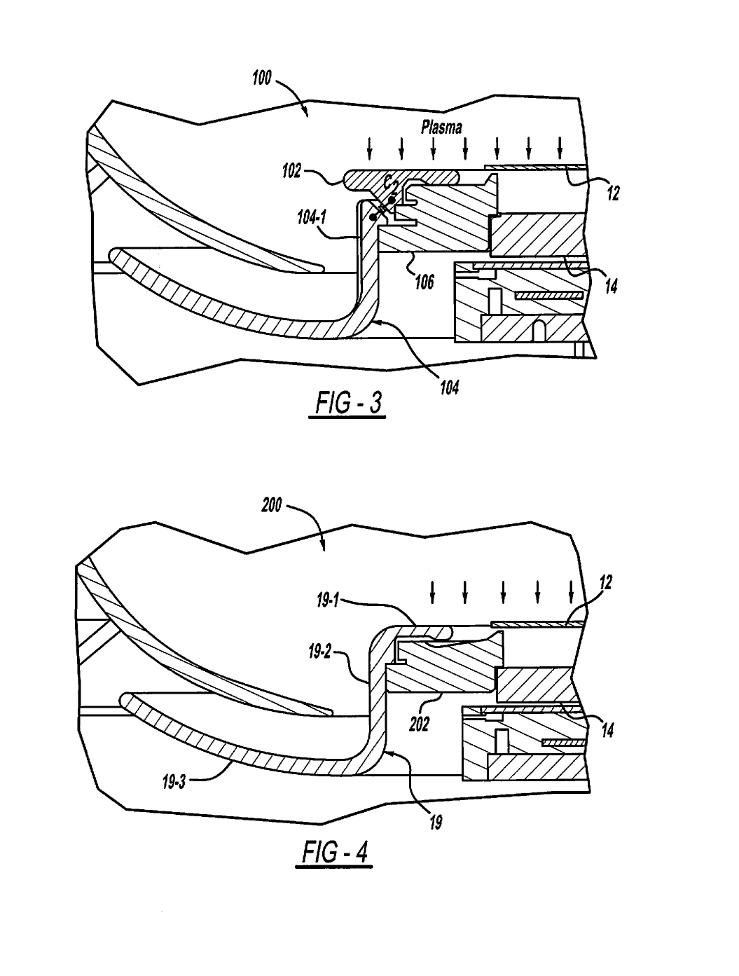

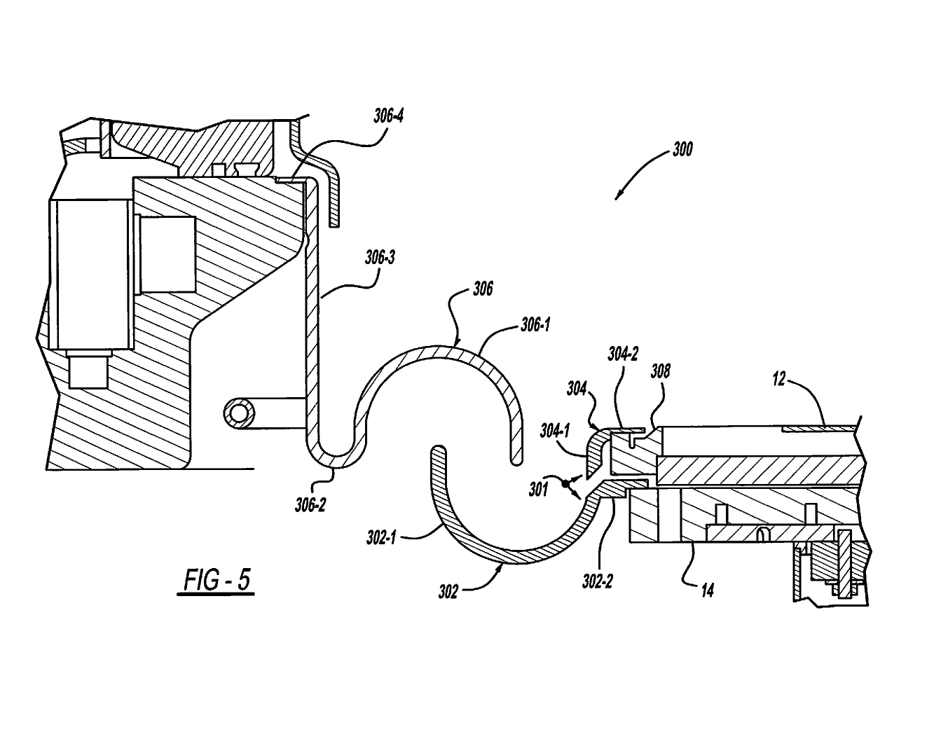

The present disclosure is organized as follows. In FIG. 3, a first arrangement of a split pedestal shield is shown. In FIG. 4, a pedestal shield arranged approximately in level with the wafer is shown. In FIG. 5, a second arrangement of a split pedestal shield is shown.

Referring now to FIG. 3, a cross-section of a portion of a processing chamber 100 including a pedestal shield according to the present disclosure is shown. The pedestal shield according to the present disclosure includes an upper shield portion 102 and a lower shield portion 104. The upper shield portion 102 and the lower shield portion 104 are annular. The upper shield portion 102 may be located at approximately the same height or level as the wafer 12. Alternatively, the upper shield portion 102 may be located below the level of the wafer 12. Leveling a top surface of the upper shield portion 102 relative to the wafer 12 in this manner improves plasma uniformity across the wafer 12.

The lower shield portion 104 is separated and electrically isolated from the upper shield portion 102 by a ring portion 106 of the pedestal 14. Specifically, the upper shield portion 102 and the lower shield portion 104 are attached to the ring portion 106. A gap separates the upper shield portion 102 and the lower shield portion 104. The ring portion 106 of the pedestal 14 is made of an electrically insulating material such as ceramic. The ring portion 106 electrically isolates the upper shield portion 102 from the lower shield portion 104.

As a result, a capacitance C₂ is created between upper and lower shield portions 102 and 104. The gap between the upper shield portion 102 and the lower shield portion 104 allows the upper shield portion 102 to closely match a floating potential of the wafer 12, especially in RF biased processes.

The gap between the upper shield portion 102 and the lower shield portion 104 also reduces RF loss through the lower shield portion 104. Reducing RF loss through the lower shield portion 104 increases a center-to-edge RF uniformity at the wafer 12.

More specifically, splitting the pedestal shield into the upper shield portion 102 and the lower shield portion 104 and lowering the top surface of the upper shield portion 102 to approximately the same height as the wafer 12 can expand the plasma boundary. Consequently, the plasma distribution at the edge of the wafer 12 tends to be the same as the plasma distribution at the center of the wafer 12 as shown.

Further, the upper shield portion 102 can be biased such that a bias difference between the upper shield portion 102 and the wafer 12 can be significantly reduced. Reducing the bias difference between the upper shield portion 102 and the wafer 12 can decrease or eliminate the lateral RF effect due to the RF bias at the edge of the wafer 12. Consequently, wafer uniformity tends to improve.

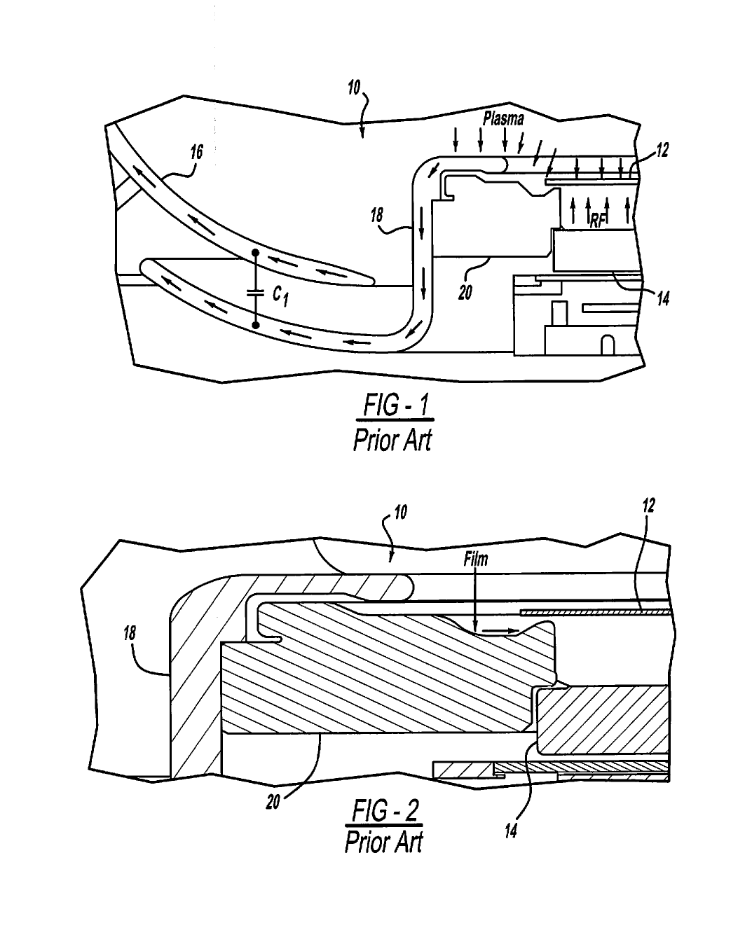

The ring portion 106 of the pedestal 14 is newly designed according to the present disclosure. For example, the ring portion 20 in FIG. 1 slopes downward towards the wafer 12 at the inner diameter of the ring portion 20. In contrast, the ring portion 106 slopes downward away from the wafer 12 at the inner diameter of the ring portion 106.

Further, as compared to the ring portion 20, the ring portion 106 has a greater slope at the inner diameter of the ring portion 106. The increased downward slope away from the wafer 12 at the inner diameter of the ring portion 106 tends to reduce film accumulation on the ring portion 106. Consequently, the ring portion 106 tends to have an increased life relative to the ring portion 20.

Additionally, a predetermined distance separates the ring portion 106 from the wafer 12. The predetermined distance depends on the type of material used to construct the ring portion 106.

More specifically, the upper shield portion 102 is attached to the ring portion 106 and is located at or below a plane including the wafer 12. The lower shield portion 104 includes a straight portion 104-1 and a curved portion 104-2. The straight portion 104-1 is perpendicular to the plane including the wafer 12. The straight portion 104-1 is attached to the ring portion 106 at a different location than the upper shield portion 102. The straight portion 104-1 extends away from the wafer 12 and toward the pedestal 14. The curved portion 104-2 extends from the straight portion 104-1 and extends away from the wafer 12 and the pedestal 14.

The upper shield portion 102 and the straight portion 104-1 of the lower shield portion 104 surround the ring portion 106. The wall shield 16 is electrically isolated from the pedestal shield and is attached to the processing chamber 100.

Referring now to FIG. 4, a cross-section of a portion of a processing chamber 200 utilizing a different arrangement of a pedestal shield 19 is shown. The pedestal shield 19 in the processing chamber 200 is different than the pedestal shield in the processing chamber 100 shown in FIG. 3. Unlike the pedestal shield in the processing chamber 100, the pedestal shield 19 in the processing chamber 200 is not split into the upper shield portion 102 and the lower shield portion 104.

Further, the pedestal shield 19 in the processing chamber 200 is arranged differently than the pedestal shield 18 in the processing chamber 10 shown in FIG. 1. Specifically, the pedestal shield 19 in the processing chamber 200 is positioned lower than the pedestal shield 18 in the processing chamber 10 such that the top surface of the pedestal shield 19 is approximately at the same height or level as the wafer 12. By leveling the pedestal shield 19 relative to the wafer 12, plasma uniformity is improved at the edge of the wafer 12 through the electrical field across the wafer 12.

The processing chamber 200 also includes the pedestal 14 having a newly designed ring 202 portion. The ring portion 202 has a different profile than the ring portion 20 used in the processing chamber 10. For example, the ring portion 20 in FIG. 1 slopes downward towards the wafer 12 at the inner diameter of the ring portion 20. In contrast, the ring portion 202 slopes downward away from the wafer 12 at the inner diameter of the ring portion 202.

Additionally, as compared to the ring portion 20, the ring portion 202 has an increased downward slope at the inner diameter of the ring portion 202. The profile (i.e., the slope characteristics) of the ring 202 portion decreases film accumulation on the inner diameter of the ring portion 202. Decreasing film accumulation on the inner diameter of the ring portion 202 tends to extend the life of the ring portion 202.

In FIG. 4, the pedestal shield 19 includes first, second, and third portions 19-1, 19-2, 19-3. The first and second portions 19-1, 19-2 are straight portions, and the third portion 19-3 is a curved portion. The first portion 19-1 is on the same plane as the wafer 12 and is therefore level with the wafer 12.

The second portion 19-2 extends perpendicularly from the first portion 19-1. The second portion 19-2 extends away from the wafer 12 and toward the pedestal 14. The third portion 19-3 extends from the second portion 19-2 and extends away from the wafer 12 and the pedestal 14. The first and the second portions 19-1, 19-2 are adjacent to the ring portion 202 as shown. The wall shield 16 is electrically isolated from the pedestal shield 19 and is attached to the processing chamber 200.

Referring now to FIG. 5, a cross-section of a processing chamber 300 including a pedestal shield 301 is shown. The pedestal shield 301 has a different geometry than the pedestal shield 18. In addition, the pedestal shield 301 can be split and arranged in different ways. For example, the pedestal shield 301 can be split into a lower shield portion 302 and an upper shield portion 304. The lower shield portion 302 and the upper shield portion 304 are annular. The arrangement of the lower shield portion 302 and the upper shield portion 304 relative to other components of the processing chamber 300 is described below. The lower shield portion 302 can be grounded to the processing chamber 300.

The processing chamber 300 further includes a wall shield 306. The wall shield 306 is grounded to the processing chamber 300. The pedestal 14 includes a ring portion 308. The ring portion 308 is made of an electrically insulating material such as ceramic.

In the example shown, the lower shield portion 302 generally has a shape of a curve (e.g., a semicircle or an arc). Specifically, the lower shield portion 302 includes a curved portion 302-1 and a straight portion 302-2. The curved portion 302-1 is concave relative to a top wall of the processing chamber 300. The straight portion 302-2 of the lower shield portion 302 is attached to the pedestal 14. The upper shield portion 304 includes first and second straight portions 304-1, 304-2 that are joined at right angle. The first straight portion 304-1 of the upper shield portion 304 is attached to the ring portion 308 and is located at or below a plane including the wafer 12.

The wall shield 306 includes a curved portion 306-1 that is similar to the curved portion 302-1 of the lower shield portion 302. The curved portion 306-1 of the wall shield 306 is concave relative to a bottom wall of the processing chamber 300. Additionally, the wall shield 306 includes first, second, and third straight portions 306-2, 306-3, 306-4. The third straight portion 306-4 of the wall shield 306 is attached to the processing chamber 300.

The geometry of the pedestal shield 301 and the manner of splitting and arranging the pedestal shield shown are for example only. The pedestal shield 301 can have a different geometry than that shown and can be split and arranged in a different manner than that shown.

In general, a capacitance C formed by two parallel conductive plates separated by a dielectric with permittivity ε can be determined as:

$$C = \frac{ɛ A}{d}$$

where C is the capacitance, A is a surface area of the conductive plates, and d is a distance between the conductive plates.

In an RF circuit comprising a capacitor C, an impedance Z of the capacitor C can be determined as:

$$Z = - \frac{j}{2 π fC}$$

where, j is an imaginary unit, and f is an RF frequency.

The lateral RF effect at the edge of the wafer 12 (i.e., the edge effect) can be reduced if the capacitance C₂ between the upper and lower pedestal shield portions is less than the capacitance C₁ between the pedestal shield and wall shield. That is, the lateral RF effect at the edge of the wafer 12 can be reduced if the following equation is satisfied:

C₂<C₁

The capacitance C₂ between the upper and lower shield portions of the pedestal shield can be decreased by increasing the distance d between the upper and lower shield portions. For example, in FIG. 3, capacitance C₂ between the upper and lower shield portions 102 and 104 can be decreased by increasing the distance d between the upper and lower shield portions 102 and 104. In FIG. 5, capacitance C₂ between the upper and lower shield portions 302 and 304 can be decreased by increasing the distance d between the upper and lower shield portions 302 and 304.

Alternatively, the capacitance C₂ between upper and lower shield portions of the pedestal shield can be decreased by decreasing the surface area A of the upper and lower shield portions. For example, in FIG. 3, capacitance C₂ between the upper and lower shield portions 102 and 104 can be decreased by decreasing the surface area A of the upper and lower shield portions 102 and 104. In FIG. 5, capacitance C₂ between the upper and lower shield portions 302 and 304 can be decreased by decreasing the surface area A of the upper and lower shield portions 302 and 304.

For a split pedestal shield, the distance between upper shield and lower shield portions should not be very large due to constraints on space available in the processing chamber. Moreover, deposition on a ceramic trench area may short-circuit the pedestal shield. Therefore, the surface area A should be smaller in order to satisfy the equation:

C₂<C₁

For example, in FIG. 1, capacitance C₁ is formed by the wall shield 16 and the pedestal shield 18. The distance d between the wall shield 16 and the pedestal shield 18 is about 0.4 in, and the area A is about 140 in². The capacitance C₁ formed by the wall shield 16 and the pedestal shield 18 is:

$${C}_{1} = \frac{ɛ A}{d} \approx \frac{ɛ \times 140}{0.4} = 350 ɛ$$

On the other hand, in FIG. 3, capacitance C₂ is formed by the upper and lower shield portions 102, 104 of the split pedestal shield. The area A is about 8 in², and the separation d between the upper and lower shield portions 102, 104 is about 0.07 in. The capacitance C_{new} is:

$${C}_{2} = \frac{ɛ A}{d} \approx \frac{ɛ \times 8}{0.07} = 114 ɛ < {C}_{1}$$

In general, the capacitance C₂ can be reduced by selecting the surface area A and the distance d and by selecting the geometry of the pedestal shield. In addition, film deposition (e.g., thickness of film) can be changed by selecting the geometry of the pedestal shield.

The arrangement of the lower shield portion 302, the upper shield portion 304, and the wall shield 306 shown in FIG. 5 is now described in detail. The curved and straight portions of the lower shield portion 302, the upper shield portion 304, and the wall shield 306 each has first and second ends.

The first end of the curved portion 302-1 of the lower shield portion 302 is collinear to a center of the curved portion 306-1 of the wall shield 306. A line joining the first end of the curved portion 302-1 and the center of the curved portion 306-1 is perpendicular to a plane along which the wafer 12 lies.

The second end of the curved portion 302-1 of the lower shield portion 302 is joined at a first junction to the first end of the straight portion 302-2 of the lower shield portion 302. The first junction is separated by a predetermined distance from the first end of the first straight portion 304-1 of the upper shield portion 304.

The second end of the first straight portion 304-1 of the upper shield portion 304 is joined at a second junction to the first end of the second straight portion 304-2 of the upper shield portion 304. The second junction surrounds the ring portion 308. The second straight portion 304-2 of the upper shield portion 304 is approximately level with the wafer 12 and is parallel to the wafer 12. That is, the second straight portion 304-2 of the upper shield portion 304 is coplanar to the wafer 12. The second end of the second straight portion 304-2 is attached to the ring portion 308.

The straight portion 302-2 of the lower shield portion 302 intersects a tangent drawn at the second end of the curved portion 302-1 of the lower shield portion 302 at right angle. The tangent is perpendicular to a diameter of the curved portion 302-1 of the lower shield portion 302. The diameter of the curved portion 302-1 of the lower shield portion 302 is parallel to the straight portion 302-2 of the lower shield portion 302.

The second end of the straight portion 302-2 of the lower shield portion 302 extends toward the pedestal 14. The second end of the straight portion 302-2 of the lower shield portion 302 is grounded to the processing chamber 300.

The straight portion 302-2 of the lower shield portion 302 is parallel to the wafer 12 and the second straight portion 304-2 of the upper shield portion 304. The straight portion 302-2 of the lower shield portion 302 is perpendicular to the first straight portion 304-1 of the upper shield portion 304.

The first end of the curved portion 306-1 of the wall shield 306 is collinear to a center of the curved portion 302-1 of the lower shield portion 302. A line joining the first end of the curved portion 306-1 and the center of the curved portion 302-1 is perpendicular to the plane along which the wafer 12 lies.

The second end of the curved portion 306-1 of the wall shield 306 is joined to the first end of the first straight portion 306-2 of the wall shield 306. The first straight portion 306-2 of the wall shield 306 intersects a tangent drawn at the second end of the curved portion 306-1 of the wall shield 306 at right angle. The tangent is perpendicular to a diameter of the curved portion 306-1 of the wall shield 306. The diameter of the curved portion 306-1 of the wall shield 306 is parallel to the first straight portion 306-2 of the wall shield 306.

The first straight portion 306-2 of the wall shield 306 is parallel to the wafer 12, the straight portion 302-2 of the lower shield portion 302, and the second straight portion 304-2 of the upper shield portion 304. The first straight portion 306-2 of the wall shield 306 is perpendicular to the first straight portion 304-1 of the upper shield portion 304. The first straight portion 306-2 of the wall shield 306 extends away from the first and second ends of the curved portion 306-1 of the wall shield 306.

The second end of the first straight portion 306-2 of the wall shield 306 is joined to the first end of the second straight portion 306-3 of the wall shield 306. The first straight portion 306-2 of the wall shield 306 is joined to the second straight portion 306-3 of the wall shield 306 at right angle. The second straight portion 306-3 of the wall shield 306 is parallel to the first straight portion 304-1 of the upper shield portion 304.

The second straight portion 306-3 of the wall shield 306 is perpendicular to the wafer 12, the second straight portion 304-2 of the upper shield portion 304, and the straight portion 302-2 of the lower shield portion 302. The second straight portion 306-3 of the wall shield 306 extends in a direction along a line drawn from the pedestal to the wafer 12.

The second end of the second straight portion 306-3 of the wall shield 306 is joined to the first end of the third straight portion 306-4 of the wall shield 306. The second end of the third straight portion 306-4 of the wall shield 306 is grounded to the processing chamber 300. The second straight portion 306-3 of the wall shield 306 is joined to the third straight portion 306-4 of the wall shield 306 at right angle.

The third straight portion 306-4 of the wall shield 306 is parallel to the wafer 12, the straight portion 302-2 of the lower shield portion 302, the second straight portion 304-2 of the upper shield portion 304, and the first straight portion 306-2 of the wall shield 306. The third straight portion 306-4 of the wall shield 306 is perpendicular to the first straight portion 304-1 of the upper shield portion 304. The third straight portion 306-4 of the wall shield 306 extends away from the wafer 12 and the pedestal 14.

In summary, the split pedestal shield with electrically isolated upper and lower shield portions protects the chamber wall and other components of the processing chamber from undesired deposition. The plasma boundary can be expanded from the edge of the wafer to an edge of the upper shield portion of the pedestal shield without impairing the ability of the lower shield portion to adequately protect the chamber wall and the ring portion from undesired deposition. The split pedestal shield tends to eliminate the lateral RF effect at the wafer edge by reducing lateral RF coupling and harmonizing an RF power vector to be vertical. Lowering the pedestal shield to the wafer level tends to improve plasma uniformity across the wafer.

Further, the life of the ring portion tends to improve by changing the profile (i.e., the slope characteristics) of the ring portion as disclosed herein. Compared to prior designs, the new designs take nearly the same amount of manufacturing time and costs. Although the new designs are developed for PVD systems, the principles described herein can be utilized in other processing chambers used to process substrates.

The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

What is claimed is:

1. A shielding system for a physical vapor deposition (PVD) chamber, the PVD chamber including a pedestal supporting a substrate, the shielding system comprising:
a first annular portion of a pedestal shield that is attached to the pedestal at a first location, wherein the first annular portion is located at or below a plane including the substrate; and
a second annular portion of the pedestal shield that is attached to the pedestal at a second location that is below the first location,
wherein the first annular portion is spaced a predetermined distance from the second annular portion and is electrically isolated from the second annular portion.

2. The shielding system of claim 1 wherein the second annular portion of the pedestal shield includes:
a straight portion that is attached to the second location, that is generally perpendicular to the plane including the substrate, and that extends from the pedestal towards a bottom chamber wall; and
a curved portion that extends from the straight portion towards a side chamber wall.

3. The shielding system of claim 2 wherein:
the first annular portion of the pedestal shield and the straight portion of the second annular portion of the pedestal shield are adjacent to a ring portion of the pedestal; and
an upper surface of the ring portion slopes downwardly from a radially inner diameter to a radially outer diameter.

4. The shielding system of claim 2 further comprising:
a wall shield,
wherein the wall shield extends inwardly from the side chamber wall towards the pedestal, and
wherein the wall shield overlaps a radially outer portion of the second annular portion of the pedestal shield.

5. The shielding system of claim 4 wherein:
the curved portion of the second annular portion of the pedestal shield is concave relative to a top chamber wall; and
the wall shield is concave relative to the top chamber wall.

6. The shielding system of claim 1 wherein the first annular portion includes:
a first portion that is attached to the pedestal and is parallel to the plane including the substrate, and
a second portion that extends in a perpendicular direction from the first portion.

7. The shielding system of claim 6 wherein the second annular portion includes:
a third portion that is attached to the pedestal at the second location and that is parallel to the plane including the substrate, and
a first curved portion that extends from the third portion towards a side chamber wall.

8. The shielding system of claim 7 wherein the first curved portion is concave relative to a top chamber wall.

9. The shielding system of claim 7 wherein:
the first, second, and third portions surround a ring portion of the pedestal; and
an upper surface of the ring portion slopes downwardly from a radially inner diameter of the ring portion to a radially outer diameter of the ring portion.

10. The shielding system of claim 7 further comprising:
a wall shield, wherein the wall shield includes:
a fourth portion that is attached to the side chamber wall, and
a second curved portion that extends from the first portion and that is concave relative to a bottom chamber wall.

11. The shielding system of claim 10 wherein:
a first end of the first curved portion is located inside the second curved portion; and
a second end of the second curved portion is located inside the first curved portion.

12. A method for shielding in a physical vapor deposition (PVD) chamber, the PVD chamber including a pedestal supporting a substrate, the method comprising:
attaching a first annular portion of a pedestal shield to the pedestal at a first location at or below a plane including the substrate;
attaching a second annular portion of the pedestal shield to the pedestal at a second location that is below the first location;
spacing the first annular portion a predetermined distance from the second annular portion; and
electrically isolating the first annular portion from the second annular portion.

13. The method of claim 12 further comprising:
attaching a straight portion of the second annular portion of the pedestal shield to the second location, wherein the straight portion is generally perpendicular to the plane including the substrate;
extending the straight portion from the pedestal towards a bottom chamber wall; and
extending a curved portion of the second annular portion of the pedestal shield from the straight portion towards a side chamber wall.

14. The method of claim 13 further comprising:
disposing the first annular portion of the pedestal shield and the straight portion of the second annular portion of the pedestal shield adjacent to a ring portion of the pedestal; and
inclining an upper surface of the ring portion to slope downwardly from a radially inner diameter to a radially outer diameter.

15. The method of claim 13 further comprising extending a wall shield inwardly from the side chamber wall towards the pedestal to overlap a radially outer portion of the second annular portion of the pedestal shield.

16. The method of claim 15 wherein:
the curved portion of the second annular portion of the pedestal shield is concave relative to a top chamber wall; and
the wall shield is concave relative to the top chamber wall.

17. The method of claim 12 further comprising:
attaching a first portion of the first annular portion to the pedestal;
disposing the first portion parallel to the plane including the substrate; and
extending a second portion of the first annular portion in a perpendicular direction from the first portion.

18. The method of claim 17 further comprising:
attaching a third portion of the second annular portion to the pedestal at the second location;
disposing the third portion parallel to the plane including the substrate; and
extending a first curved portion of the second annular portion from the third portion towards a side chamber wall.

19. The method of claim 18 wherein the first curved portion is concave relative to a top chamber wall.

20. The method of claim 18 wherein:
disposing the first, second, and third portions to surround a ring portion of the pedestal; and
inclining an upper surface of the ring portion to slope downwardly from a radially inner diameter of the ring portion to a radially outer diameter of the ring portion.

21. The method of claim 18 further comprising:
attaching a fourth portion of a wall shield to the side chamber wall; and
extending a second curved portion of the wall shield from the fourth portion,
wherein the second curved portion is concave relative to a bottom chamber wall.

22. The method of claim 21 further comprising:
disposing a first end of the first curved portion inside the second curved portion; and
disposing a second end of the second curved portion inside the first curved portion.

23. A physical vapor deposition (PVD) chamber, comprising:
a pedestal supporting a substrate, wherein the pedestal includes a ring portion, and wherein an upper surface of the ring portion slopes downwardly from a radially inner diameter of the ring portion to a radially outer diameter of the ring portion;
a first annular portion of a pedestal shield that is attached to the pedestal and that is located at or below a plane including the substrate; and
a second annular portion of the pedestal shield that includes a straight portion and a first curved portion,
wherein the straight portion is generally perpendicular to the plane including the substrate and extends from the first annular portion towards a bottom chamber wall,
wherein the first curved portion extends from the straight portion towards a side chamber wall, and
wherein the first annular portion and the straight portion are adjacent to the ring portion of the pedestal.

24. The PVD chamber of claim 23 further comprising:
a wall shield including:
a first portion that is attached to the side chamber wall; and
a second curved portion that extends towards the pedestal.

25. The PVD chamber of claim 24 wherein the first curved portion of the pedestal shield overlaps the second curved portion of the wall shield.

26. The PVD chamber of claim 24 wherein:
the first curved portion of the pedestal shield is concave relative to a top chamber wall; and
the second curved portion of the wall shield is concave relative to the top chamber wall.

27. A method for shielding in a physical vapor deposition (PVD) chamber, comprising:
arranging a pedestal configured to support a substrate in the PVD chamber,
configuring an upper surface of a ring portion of the pedestal to slope downwardly from a radially inner diameter of the ring portion to a radially outer diameter of the ring portion;
attaching a pedestal shield including a first annular portion and a second annular portion to the pedestal, wherein the second annular portion includes a straight portion and a first curved portion;
arranging the first annular portion of the pedestal shield at or below a plane including the substrate;
arranging the straight portion generally perpendicular to the plane including the substrate, wherein the straight portion extends from the first annular portion towards a bottom chamber wall; and
arranging the first curved portion to extend from the straight portion towards a side chamber wall,
wherein the first annular portion and the straight portion are adjacent to a ring portion of the pedestal.

28. The method of claim 27 further comprising:
attaching a wall shield to the side chamber wall, wherein the wall shield includes a first portion that is attached to the side chamber wall and a second curved portion that extends towards the pedestal.

29. The method of claim 28 further comprising overlapping the first curved portion of the pedestal shield with respect to the second curved portion of the wall shield.

30. The method of claim 28 wherein:
the first curved portion of the pedestal shield is concave relative to a top chamber wall; and
the second curved portion of the wall shield is concave relative to the top chamber wall.
